(19) United States
(12) Patent Application Publication
(10) Pub. No.: US 2011/0180002 A1
(43) Pub. Date: Jul. 28, 2011

(54) VAPORIZER AND DEPOSITION SYSTEM USING THE SAME

(75) Inventors: Sumi Tanaka, Yamanashi (JP); Munehisa Futamura, Yamanashi (JP)

(73) Assignee: TOKYO ELECTRON LIMITED, Tokyo (JP)

(21) Appl. No.: 13/121,238

(22) PCT Filed: Jun. 12, 2009
(86) PCT No.: PCT/JP2009/060762

§ 371 Date: Mar. 28, 2011

(30) Foreign Application Priority Data
Sep. 30, 2008 (JP) 2008-253574

(51) Int. Cl. C23C 16/448; C23C 16/455

(52) U.S. Cl. 118/726

(57) ABSTRACT

To prevent a liquid material outlet from being clogged with accretion. Disclosed is a vaporizer, which vaporizes a liquid material, discharged from the outlet of a nozzle, in a heated vaporization chamber to produce a raw gas, and which is provided with a cylindrical heated member, which is disposed between the front end of the nozzle and the vaporization chamber so as to cover the perimeter of the outlet, a carrier gas ejection port, which ejects a carrier gas from the vicinity of the outlet, a mixing chamber, wherein the liquid material discharged from the outlet is mixed with the carrier gas, which ejects the mixture toward the vaporization chamber, a first heating part, which heats the vaporization chamber from its exterior, and a second heating part, which heats the heated member from its exterior.

### FIELD OF THE INVENTION

The present invention relates to a vaporizer that produces a raw material gas by vaporizing a liquid material and a deposition system using the vaporizer.

### BACKGROUND ART

In general, as a film forming method for forming various thin films formed with dielectric material, metal, semiconductor and the like, a chemical vapor deposition (CVD) method has been known in which an organic raw material such as an organo-metallic compound is supplied to a film forming chamber to form films by allowing the organic raw material to react with other gases such as oxygen or ammonia. Since the organic raw material used for such CVD method is often a liquid state under the room temperature and a normal pressure, there is a need for the organic raw material to be gasified to be supplied to the film forming chamber. Therefore, typically, the organic raw material in the liquid state is vaporized in a vaporizer to form a raw gas.

For example, according to the patent document 1 as listed below, a carrier gas in a high temperature flows between the discharge outlet of the liquid material outflow path (nozzle) and a diaphragm valve, and the liquid material discharged from the discharge outlet is vaporized to form a raw gas. Also, according to patent documents 2 and 3 as listed below, the oscillation of an ultrasonic wave oscillator is delivered to the liquid material discharged from a liquid material outlet portion (for example, nozzles, pipes, holes and the like) to make dropletization (mistization) of the liquid material. The flow of a carrier gas is then formed near the discharge outlet of the liquid material, and the liquid material in a droplet shape is placed to the flow of the carrier gas. Subsequently, the liquid material in the droplet shape is transferred to a heating place and vaporized to form the raw gas.

### Patent Documents

Patent Document 1: Japanese Patent Application Laid-Open Publication No. Heisei 8-200525. Patent Document 2: Japanese Patent Application Laid-Open Publication No. Heisei 11-16839. Patent Document 3: Japanese Patent Application Laid-Open Publication No. 2001-89861. Patent Document 4: Japanese Patent Application Laid-Open Publication No. 2001-262350.

### DISCLOSURE OF THE INVENTION

### Problems to be Solved

However, in a conventional vaporizer in which the flow of the carrier gas is formed near the discharge outlet that discharges the liquid material as described above, there was a problem that the components of the liquid material, depending on the kind of liquid material, react with the small amount of moisture included in the carrier gas, and are solidificated. Examples of such liquid materials include an organo-metallic compound such as TEMA, TEMAZ (tetrakis ethylmethylamino zirconium) and TEMAH (tetrakis ethylmethylamino hafnium).

Also, generally, a vaporizer is configured to make droplets as small as possible by making the orifice of the nozzle discharging the liquid material to be small, in order to vaporize the liquid material effectively. Therefore, there also is a concern that if the liquid material including the composition that is easy to react with the moisture as described above is discharged from the discharge outlet, the product (an oxide) made by the reaction with the moisture included in the carrier gas flowing near the discharge outlet is attached and deposited to the discharge outlet, thereby blocking the discharge outlet by the undesired accretion. With this, an enough flow of the raw gas may not be obtained. Additionally, since the replacement or cleaning of the nozzles should be frequently needed, the throughput of the process is decreased.

Also, in the case where the carrier gas is flowed between the discharge outlet of the nozzle and a diaphragm and vaporized as disclosed in patent document 1, if the entire portion where the diaphragm valve and nozzle are provided is heated in order to improve a vaporization efficiency as in patent document 4, it is undesirable because even the liquid material flowing in the nozzle is likely to be thermally decomposed, as the heating temperature becomes high. On the contrary, as the heating temperature becomes low, the vaporization efficiency of the liquid material is decreased.

Accordingly, the present invention has been made in view of the aforementioned problems, and is to provide a vaporizer and a deposition system using the vaporizer that are capable of preventing the discharge outlet of the liquid material from being clogged by the accretion, when the raw gas is produced by vaporizing the liquid material discharged from the discharge outlet of the nozzle inside the heated vaporization chamber.

### Means to Solve the Problem

The present inventors conducted experiments repeatedly, and found out that the accretions are not attached to the discharge outlet by heating the discharge outlet of the liquid material, even if the discharge outlet is exposed to the carrier gas. The present invention has been made in view of this point.

In order to solve the above problems, according to an aspect of the present invention, there is provided a vaporizer including a liquid storage chamber that is supplied with a liquid material with a predetermined pressure; a nozzle disposed projecting from the liquid storage chamber and configured to discharge the liquid material from the liquid storage chamber; a vaporization chamber that vaporizes the liquid material discharged from the discharge outlet of the nozzle to produce a raw gas to be delivered from a delivery outlet; a cylindrical heated member provided to cover the perimeter of the discharge outlet between the front end of the nozzle and the vaporization chamber; a carrier gas ejection port provided at the heated member and configured to eject the carrier gas from the vicinity of the discharge outlet; a mixing chamber partitioned within the heated member and configured to mix the liquid material discharged from the discharge outlet with the carrier gas to eject the mixture to the vaporization chamber; a first heating part configured to heat the vaporization chamber from the exterior; and a second heating part configured to heat the heated member from the exterior.

In order to solve the above problems, according to another aspect of the present invention, there is provided a deposition system having a film forming chamber that performs a film forming process on a substrate to be processed by introducing a raw gas from a vaporizer that vaporizes a liquid material to produce the raw gas. The vaporizer is characterized by including a liquid storage chamber that is supplied with a liquid material with a predetermined pressure, a nozzle projected from the liquid storage chamber and configured to discharge the liquid material from the liquid storage chamber, a discharge outlet opened at the front end of the nozzle, a vaporization chamber that vaporizes the liquid material discharged from the discharge outlet to produce the raw gas, a delivery outlet configured to deliver the raw gas from the vaporization chamber to the film forming chamber, a cylindrical heated member provided to cover the perimeter of the discharge outlet between the front end of the nozzle and the vaporization chamber, a carrier gas ejection port provided at the heated member and configured to eject the carrier gas from the vicinity of the discharge outlet, a mixing chamber partitioned within the heated member and configured to mix the liquid material discharged from the discharge outlet with the carrier gas to eject the mixture to the vaporization chamber, a first heating part configured to heat the vaporization chamber from the exterior, and a second heating part configured to heat the heated member from the exterior.

According to the invention as described above, the droplets of the liquid material discharged from the discharge outlet of the nozzle are mixed with the carrier gas discharged from the carrier gas ejection port at the mixing chamber within the heated member, and ejected toward the vaporization chamber heated by the first heating part. As a result, the droplets of the liquid material are vaporized at the vaporization chamber and become a raw gas to be delivered from the delivery outlet to an outside (for example, a film forming chamber).

At this time, it is possible to partially heat the discharge outlet of the nozzle to the temperature that the accretion is not attached to the discharge outlet, by heating the heated member with the second heating part without lowering the heating temperature of the vaporization chamber. By such heating temperature of the heated member, the liquid material is not thermally decomposed during the flowing toward the discharge outlet, and the accretion is prevented from being attached to the discharge outlet.

Also, it is possible to heat even the mixing chamber in which the liquid material and the carrier gas are mixed, as well as the discharge outlet of the liquid material by heating the heated member. Accordingly, since the moisture included in the carrier gas that results in producing the accretion can be vaporized at the mixing chamber efficiently, it is possible to prevent the accretion from being attached to the discharge outlet more effectively.

Also, it is preferable that the heated member is made of metal, and the nozzle is made of resin. Then, it is possible to effectively prevent the entire nozzle from being heated, since the heat from the heated member cannot be delivered easily. Therefore, it is possible to prevent the accretion from being attached to the discharge outlet more effectively without thermally decomposing the liquid material flowing within the nozzle in the middle of flowing, even if the heating temperature by the second heating part is set to be high.

Also, it is preferable that the mixing chamber is partitioned by a throttle portion provided at the heated member that the throttle portion is formed with a throttle hole communicating between the mixing chamber and the vaporization chamber, and that the throttle portion is configured to be heated along with the heated member by the second heating part. With these features, the droplets of the liquid material discharged from the discharge outlet are mixed with the carrier gas at the mixing chamber, accelerated by the throttle hole of the throttle portion, and ejected toward the vaporization chamber. Accordingly, it is possible to make the droplets of the liquid material finer, and provide the droplets stably to the vaporization chamber, along with the carrier gas.

Also, it is preferable that the mixing chamber is formed with a central space at the lower side of the discharge outlet and a ring-shaped space surrounding the central space. It is preferable that the carrier gas ejection port is arranged to eject the carrier gas to the ring-shaped space. With these features, the carrier gas ejected from the carrier gas ejection port is spread to the ring-shaped space, allowing the carrier gas to flow from the entire ring-shaped space to the central space. Therefore, the droplets of the liquid material discharged from the discharge outlet can be guided to the throttle hole efficiently.

Also, it is preferable that an upper tapered portion is provided at the mixing chamber side of the throttle portion allowing the diameter of the throttle hole to be enlarged gradually toward the mixing chamber, and the upper tapered portion is formed to be projected toward the discharge outlet. According to this, the wall surface of the ring-shaped space can be provided at further outer side than the upper tapered portion at the mixing chamber, by providing the upper tapered portion to be projected at the mixing chamber. Also, since the throttle hole is enlarged toward an entrance side (an upstream side), it is possible to easily guide the carrier gas from the ring-shaped space to the central space.

In this case, a lower tapered portion is provided at the vaporization chamber side of the throttle portion, allowing the diameter of the throttle hole to be enlarged gradually toward the vaporization chamber, and the lower tapered portion may be formed to be projected toward the vaporization chamber. With these features, the flow rates of the droplets of the liquid material and the carrier gas discharged from the throttle hole can be even more increased, since the throttle hole is enlarged toward the exit side (downstream side). Therefore, it is possible to make the liquid material to become finer droplets, thereby providing the finer droplets to the vaporization chamber.

Also, there may be provided a first temperature sensor configured to detect the temperature of the vaporization chamber, and a second temperature sensor configured to detect the temperature of the discharge outlet. There may also be provided a controller configured to monitor the temperatures of each of the temperature sensors, control the temperature of the discharge outlet to such a degree that at least the accretions are not attached to the discharge outlet, and control the temperature of the vaporization chamber to be set higher than the temperature of the discharge outlet.

According to these features, the vaporization efficiency at the vaporization chamber can be improved, while maintaining the temperature of the discharge outlet to such a degree that at least the accretions are not attached to the discharge outlet. In addition, the temperature of the vaporization chamber maybe set to be higher than that of the discharge outlet, so that the temperature gradient can be formed in such a way that the temperature becomes high from the upstream side to the downstream side as seen from the whole vaporizer. In other words, the part that the liquid material flows is the lowest in the temperature, the discharge outlet is heated in such a degree that the accretions are not attached to the discharge outlet, and the vaporization chamber is heated to a higher temperature. Therefore, the liquid material is not thermally decomposed in a way to the discharge outlet after passing a fine hole, the accretions can be prevented from being attached to the discharge outlet, and the vaporization efficiency at the vaporization chamber can be improved.

### EFFECT OF THE INVENTION

According to the present invention, it is possible to prevent the discharge outlet of the liquid material from being clogged by accretions, and also to improve the vaporization efficiency at the vaporization chamber, since the discharge outlet of the liquid material can be partially heated and separately from the vaporization chamber.

### BRIEF DESCRIPTION OF THE DRAWINGS

FIG. 1 is a view showing a schematic constitution of the deposition system according to an embodiment of the present invention.

FIG. 2 is a vertical cross-sectional view showing a schematic constitution of the vaporizer according to the embodiment.

FIG. 3 is a partially enlarged view showing the vaporizer according to the embodiment.

FIG. 4 is a partially enlarged view showing the modified example of the vaporizer according to the embodiment.

### DETAILED DESCRIPTION

Hereinafter, preferred embodiments of the present invention will be described in detail, with reference to the attached drawings. In addition, throughout the specification and the drawings, same reference numbers are used to represent the components having substantially same functions and configuration, and the description thereof is omitted for clarity.

### Deposition System

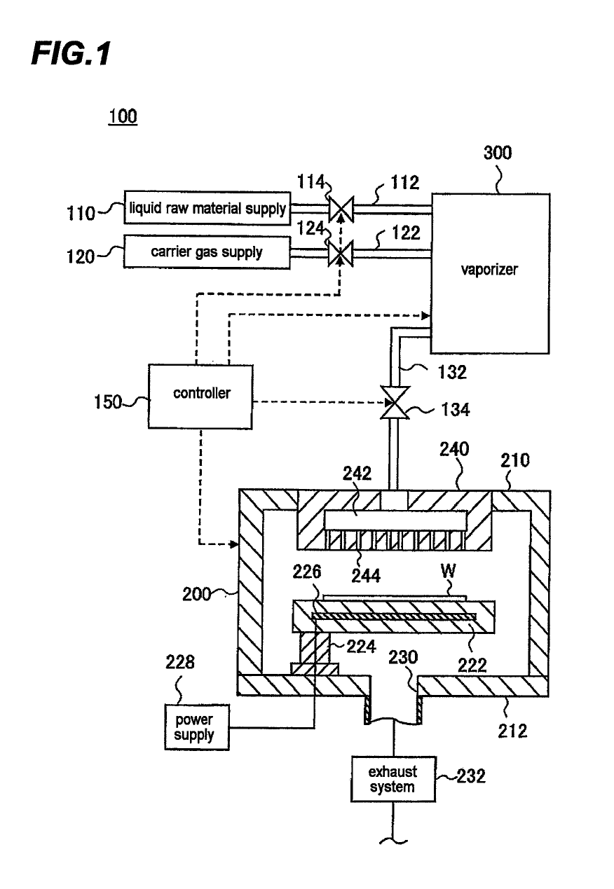

First, the deposition system according to the embodiment of the present invention will be described with reference to the drawings. FIG. 1 is a view for illustrating an example of the schematic constitution of the deposition system according to the embodiment of the present invention. A deposition system 100 shown in FIG. 1 is configured to form a metal oxide film on a substrate to be processed, for example, a semiconductor waver (hereinafter, “wafer”) W by a CVD method. Deposition system 100 includes a liquid material supply 110 configured to supply a liquid material including an organic compound containing Hf (hafnium), a carrier gas supply 120 configured to supply a carrier gas, a vaporizer 300 configured to vaporize the liquid material supplied from liquid material supply 110 and produce a raw gas, a film forming chamber 200 configured to use the raw gas produced by vaporizer 300 and form, for example, HfO₂ film on wafer W, and a controller 150 configured to control each of components of deposition system 100. Also, as the carrier gas, an inert gas, for example, Ar and the like may be used.

Liquid material supply 110 and vaporizer 300 are connected through a liquid material supply pipe 112, carrier gas supply 120 and vaporizer 300 are connected through a carrier gas supply pipe 122, and vaporizer 300 and film forming chamber 200 are connected through a raw gas supply pipe 132. In addition, liquid material supply pipe 112 is provided with a liquid material flow control valve 114, carrier gas supply pipe 122 is provided with a carrier gas flow control valve 124, and raw gas supply pipe 132 is provided with a raw gas flow control valve 134. The opening degrees of each of liquid material flow control valve 114, carrier gas flow control valve 124, and raw gas flow control valve 134 is adjusted by the control signal of controller 150. It is preferable that controller 150 outputs the control signal according to the flow rate of the liquid material flowing at liquid material supply pipe 112, the flow rate of the carrier gas flowing at carrier gas supply pipe 122, and the flow rate of the raw gas flowing at raw gas supply pipe 132.

Film forming chamber 200 includes, for example, a substantially cylindrical sidewall, and a susceptor 222 in which wafer W is disposed horizontally at the inner space surrounded by the sidewall, a ceiling wall 210, and a bottom wall 212. The sidewall, ceiling wall 210, and bottom wall 212 are made of metal, such as aluminum, stainless. Susceptor 222 is supported by a plurality of cylindrical support members 224 (only one of the support members is shown in this figure). Also, a heater 226 is buried at susceptor 222 so as to adjust the temperature of wafer W disposed at susceptor 222, by controlling the power supplied from power supply 228 to heater 226.

An exhaust port 230 is formed on bottom wall 212 of film forming chamber 200, and an exhaust system 232 is connected to exhaust port 230. And the pressure of film forming chamber 200 can be reduced to a predetermined vacuum degree by exhaust system 232.

A shower head 240 is attached on ceiling wall 210 of film forming chamber 200. Raw gas supply pipe 132 is connected to shower head 240, and the raw gas produced at vaporizer 300 is introduced to show head 240 via raw gas supply pipe 132. Shower head 240 includes a diffusion chamber 242, and a plurality of gas discharge holes 244 communicating with diffusion chamber 242. The raw gas introduced to diffusion chamber 242 of shower head 240 through raw gas supply pipe 132 is discharged toward wafer W on susceptor 222 from gas discharge hole 244.

In deposition system 100 according to the present embodiment, liquid material supply 110 stores the liquid material, for example, HTB (hafnium tert-butoxide), and sends out the liquid material toward vaporizer 300 via liquid material supply pipe 112.

In deposition system 100 with such configuration, the raw gas from vaporizer 300 is supplied as described below. When the liquid material from liquid material supply 110 is supplied to vaporizer 300 via liquid material supply pipe 112, and the carrier gas from carrier gas supply 120 is supplied to vaporizer 300 via carrier gas supply pipe 122, droplets are made from the liquid material with the carrier gas and discharged out at the vaporization chamber provided at vaporizer 300, so that this liquid material is vaporized to produce the raw gas. The raw gas produced at vaporizer 300 is supplied to film forming chamber 300 via raw gas supply pipe 132, so that a desired film forming process is performed on wafer W at film forming chamber 200. The concrete configuration example of vaporizer 300 will be described later.

### Configuration Example of a Vaporizer

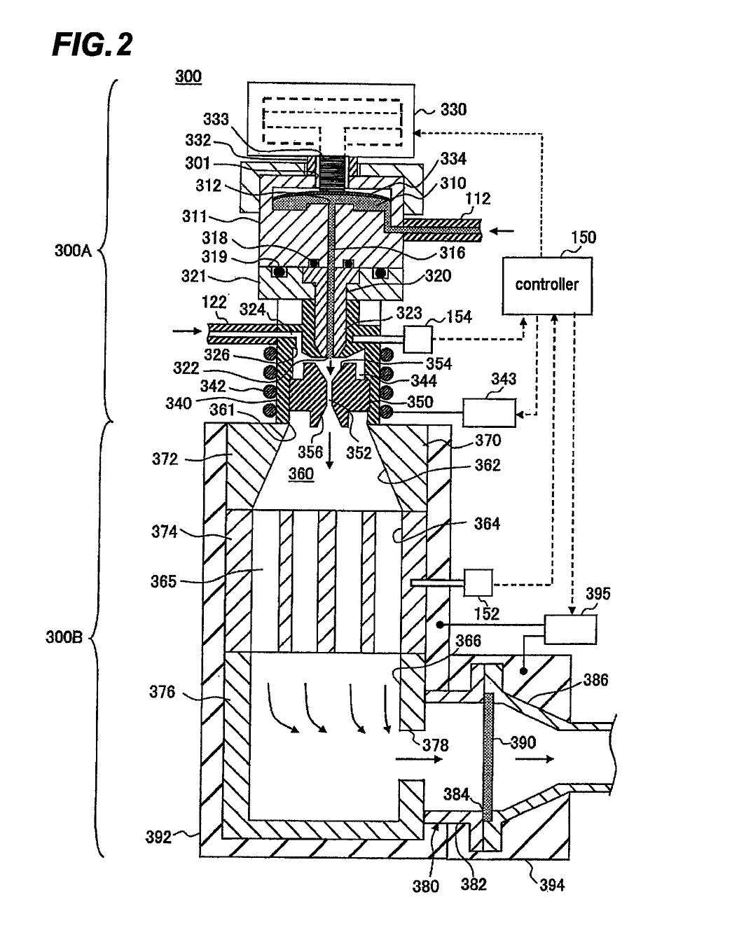

Hereinafter, a concrete configuration example of vaporizer 300 according to the present embodiment will be described with reference to the drawings. FIG. 2 is a vertical cross-sectional view showing a schematic configuration of the vaporizer according to the present embodiment. As shown in FIG. 2, vaporizer 300 includes, as divided roughly, a liquid material supply 300A configured to discharge the liquid material with droplets shape (mist shape), and a raw gas generator 300B including a vaporization chamber 360 that produces the raw gas by vaporizing the discharged liquid material in droplets shape.

First, liquid material supply 300A will be described. Liquid material supply 300A includes a liquid storage chamber 310 configured to retain the liquid material supplied with a predetermined pressure from liquid material supply pipe 112 temporarily, a nozzle 320 disposed to be projected downward from liquid storage chamber 310, a fine hole 316 that forms a flow path for flowing the liquid material at liquid storage chamber 310 to discharge outlet 322 of nozzle 320, a valve body 334 configured to open and close a liquid entrance 312 at the side of liquid storage chamber 310 of fine hole 316, and an actuator 330 configured to drive valve body 334.

Specifically, liquid material supply 300A includes a liquid material introduction 311 in which the liquid material is introduced. Liquid material introduction 311 is formed with a convex-shape metal made of aluminum or stainless steel and the like, and includes liquid storage chamber 310 being partitioned therein. Liquid storage chamber 310 is adapted to be supplied with the liquid material via liquid material supply pipe 112 with a predetermined pressure.

Liquid material introduction 311 is provided with nozzle 320 projecting downward. Nozzle 320 of the present embodiment is made of resin such as, for example, polyimide or Teflon (registered trade mark), so as not to transfer heat from an environment.

A base end of nozzle 320 is fixed to the bottom plane of liquid material introduction 311 by an attachment member 321 formed with a convex-shape metal such as aluminum or stainless steel. The contact surface between liquid material introduction 311 and attachment member 321 is sealed with, for example, O-ring and the like. Specifically, O-ring 318 is provided between liquid material introduction 311 and nozzle 320, and O-ring 319 is provided between liquid material introduction 311 and attachment member 321.

At the bottom of liquid material introduction 311, fine hole 316 is provided penetrating from liquid storage chamber 310 to discharge outlet 322 via a front end 323 of nozzle 320. Accordingly, the liquid material within liquid storage chamber 310, when introduced from liquid entrance 312 at the side of liquid storage chamber 310 of fine hole 316, is passed through nozzle 320 and discharged from discharge outlet 322.

Liquid entrance 312 of fine hole 316 is opened and closed by a flexible valve body 334 such as, for example a diaphragm valve. Liquid storage chamber 310 is partitioned by valve body 334 and the inner walls of liquid material introduction 311. Valve body 334 is attached to actuator 330 which adjusts the opening/closing and the opening degree of the valve.

Actuator 330 is provided at the ceiling of liquid storage chamber 310. Specifically, actuator 330 is attached through a cylindrical attachment member 332 provided to surround a penetrating hole 301 formed at the ceiling of liquid storage chamber 310. At the approximate center of actuator 330, a driving rod 333 is provided through penetrating hole 301. Driving rod 333 is driven an up and down direction by the movement of actuator 330.

Actuator 330 is configured to move driving rod 333 to an up and down direction, for example, with a housing-shaped electromagnetic coil, and valve body 334 is attached to the lower end of driving rod 333. With this feature, liquid entrance 312 can be opened and closed by bending valve body 334 in association with the movement of driving rod 333.

For example, actuator 330 is connected to controller 150, and driving rod 333 is driven based on the control signal from controller 150. As a result, valve body 334 is driven by moving driving rod 333 of actuator 330 to the up and down direction based on the control signal from controller 150, so that valve body 334 can be opened and closed.

In addition, the valve opening degree of valve body 334 can be adjusted by adjusting the position of driving rod 333 of actuator 330 based on the control signal from controller 150. As stated above, by adjusting the valve opening degree of valve body 334, the flow rate of liquid material discharged from discharge outlet 322 can be adjusted since the liquid material introduced from liquid entrance 312 of fine hole 316 can be adjusted. And the supply of the liquid material discharged from discharge outlet 322 can be stopped, by allowing driving rod 333 to be driven to a complete closing condition until valve body 334 is sealed to liquid entrance 312.

Also, actuator 330 is not limited to the electromagnetic driving member as described above, and may adopt, for example, a piezoelectric element.

At vaporizer 300 according to the present embodiment, heated member 340 is provided for partially heating discharge outlet 322 between front end 323 of nozzle 320 and vaporization chamber 360, in order to prevent the accretion from being attached to discharge outlet 322 of nozzle 320. The top end of heated member 340 is attached to attachment member 321 of nozzle 320, and the low end thereof is attached to raw gas generator 300B.

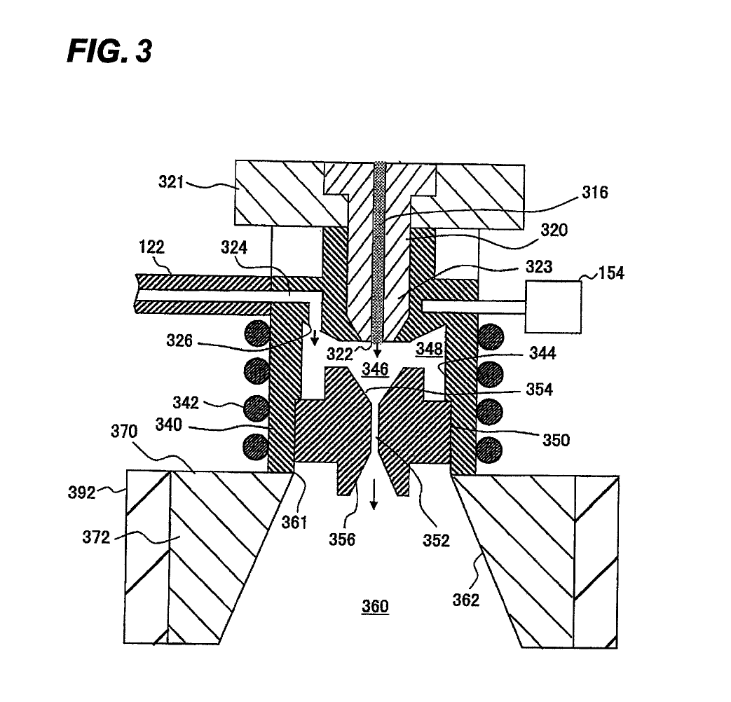

Hereinafter, such heated member 340 will be described in more detail with reference to the drawings. FIG. 3 is an enlarged view for showing the configuration of the vicinity of the heated member. As shown in FIGS. 2 and 3, heated member 340 is formed with a substantially cylindrical metal made of aluminum or stainless steel and the like, and the top portion thereof is configured to cover front end 323 of nozzle 320, particularly, the perimeter of discharge outlet 322.

A carrier gas ejection port 326 is provided at heated member 340 for ejecting the carrier gas from the vicinity of discharge outlet 322. Carrier gas ejection port 326 is in communication with a carrier gas supply passage 324 provided at heated member 340. Carrier gas supply passage 324 is connected to carrier gas supply pipe 122. Accordingly, the carrier gas from carrier gas supply pipe 122 is ejected from carrier gas ejection port 326 via carrier gas supply passage 324.

The inner side of the lower end of heated member 340 is connected to an inlet 361 of vaporization chamber 360. Within heated member 340, a mixing chamber 344 is provided at the lower side of discharge outlet 322, in which the liquid material discharged from discharge outlet 322 is mixed with the carrier gas discharged from carrier gas ejection port 326 and the mixture is discharged to vaporization chamber 360.

Specifically, mixing chamber 344 is partitioned by a throttle portion 350 provided at heated member 340 and the inner walls of heated member 340. A throttle hole 352 is provided at throttle portion 350 for communicating mixing chamber 344 and vaporization chamber 360. With this feature, the droplets of the liquid material ejected from discharge outlet 322 is mixed with the carrier gas ejected from carrier gas ejection port 326 in mixing chamber 344, and the mixture is discharged toward vaporization chamber 360 after passing throttle hole 352. At this time, the flow velocity of the droplets of the liquid material and the carrier gas get fast by the effect of throttle hole 352.

Such throttle portion 350 is constituted, for example, as shown in FIG. 3. At mixing chamber 344 side of throttle portion 350 shown in FIG. 3, an upper taper portion 354 is provided to be projected toward discharge outlet 322 by allowing the diameter of throttle hole 352 to become gradually increased toward mixing chamber 344. At vaporization chamber 360 side of throttle portion 350, a lower taper portion 356 is provided to be projected toward vaporization chamber 360 by allowing the diameter of throttle hole 352 to become gradually increased toward vaporization chamber 360.

According to this, the droplets of the liquid material discharged from discharge outlet 322 is mixed with the carrier gas at mixing chamber 334, and the mixture is discharged toward vaporization chamber 360 after the flow velocity thereof becomes faster by throttle hole 352. Thereby, it is possible to make the droplets of the liquid material finer, and stably provide the droplets toward vaporization chamber 360 along with the carrier gas.

It is preferred that mixing chamber 344 is constituted by a ring-shaped space 348 surrounding a center space 346 at the lower side of discharge outlet 322 and the vicinity thereof. Specifically, for example, in FIG. 3, the wall surface of ring-shaped space 348 can be formed by obliquely making the upper part near the side wall (for example, the part in which carrier gas ejection port 326 is provided) of the inner wall of heated member 340 partitioning mixing chamber 344. Also, as shown in FIG. 3, the wall surface of ring-shaped space 348 can be formed further outside than upper taper portion 354 at mixing chamber 344, by providing upper taper portion 354 to be projected toward mixing chamber 344.

As described above, mixing chamber 344 is constituted by center space 346 of the lower side of discharge outlet 322 and ring-shaped space 348 surrounding center space 346, and carrier gas ejection port 326 is disposed to eject the carrier gas to ring-shaped space 348. As a result, the carrier gas discharged form carrier gas ejection port 326 is distributed to ring-shaped space 348 and flows from the entire ring-shaped space 348 to center space 346. Accordingly, the droplets of the liquid material discharged from discharge outlet 322 can be effectively introduced to throttle hole 352. Also, by constituting throttle portion 350 as shown in FIG. 3, the introduction of the carrier gas from ring-shaped space 348 to center space 346 can be facilitated because throttle hole 352 is enlarged toward the entrance side (upstream side).

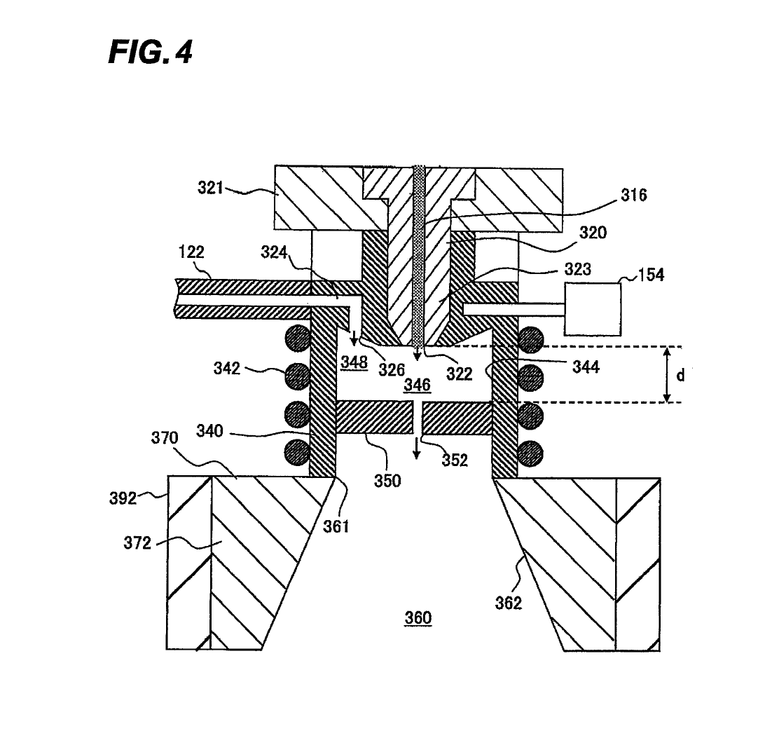

Also, by constituting throttle portion 350 as shown in FIG. 3, since throttle hole 352 is enlarged toward an exit side (downstream side), the flow velocity of the droplets of the liquid material and the carrier gas discharged from throttle hole 352 can be higher. Additionally, the configuration of throttle portion 350 is not limited to that shown in FIG. 3. For example, as shown in FIG. 4, throttle portion 350 may be in a disk-shape, and throttle hole 352 may be formed in the center of the disk.

In addition, as shown in FIG. 4, the flow velocity of the droplets of the liquid material and the carrier gas discharged from throttle hole 352 varies depending on the distance d between discharge outlet 322 and throttle portion 350. Accordingly, it is preferable that throttle portion 350 is positioned so as to optimize the distance d depending on the desired flow velocity. Also, this point is the same as in the configuration shown in FIG. 3.

A coil-shaped heater 342 is provided outside heated member 340. Heater 342 is provided at the narrow area from discharge outlet 322 of nozzle 320 to the lower end of heated member 340. Accordingly, the vicinity of discharge outlet 322 of heated member 340 can be partially heated. Heater 342 is formed with, for example, a resistive heat-generating heater. The heat-generating temperature of heater 342 is controlled by controlling heater power source 343 through controller 150.

According to this constitution, discharge outlet 322 of the liquid material can be heated partially to such a temperature that the accretion is not attached (for example, 100° C. or higher), by heating heated member 340 through heater 342. Accordingly, it is possible to prevent the accretion from being attached to discharge outlet 322. Moreover, by heating heated member 340, it is possible to heat even mixing chamber 344 in which the liquid material and the carrier gas are mixed, as well as discharge outlet 322 of the liquid material. Thereby, since the moisture which is a factor to form the accretion (i.e., the moisture contained at the carrier gas) can be vaporized efficiently, it is possible to prevent the accretion from being attached to discharge outlet 322 more effectively.

Moreover, since nozzle 320 is made of resin in the present embodiment, fine hole 316 within nozzle 320 can be prevented from being heated effectively, even if heated member 340 is heated. Therefore, even if the heating temperature of heated member 340 becomes higher, the liquid material that passes through fine hole 316 may not be thermally decomposed, and it is possible to prevent the accretion from being attached to discharge outlet 322.

Next, raw gas generator 300B is described. Raw gas generator 300B includes a substantially cylindrical case 370 that partitions vaporization chamber 360, and a raw gas delivery outlet 380 provided at the lower side of case 370. Case 370 and raw gas delivery outlet 380 are made of, for example, aluminum or stainless steel. Case 370 and raw gas delivery outlet 380 are covered with heaters 392, 394 working as a first heating part. Heaters 392, 394 are formed with, for example, a resistive heat-generating heater. In this case, the heat-generating temperature of heaters 392, 394 is adjusted by controlling a heater power source 395. Accordingly, raw material generator 300B can be heated to a predetermined temperature, for example, higher than the vaporizing temperature of the liquid material.

Herein, case 370 is constituted by connecting an upper case 372, a middle case 374, and a lower case 376 using a connection member, such as bolts which is not shown. Vaporization chamber 360 is formed with a diffusion space 362 formed at upper case 372, a guide space 364 formed at middle case 374, and an outlet space 366 formed at lower case 376.

The diameter of diffusion space 362 is gradually enlarged from inlet 361 toward the lower side, and the lower end of diffusion space 362 is provided consecutively with guide space 364. Guide space 364 herein is constituted with a plurality of guide holes 365 provided vertically from the upper side to the lower side, in order to heat the droplets of the liquid material efficiently. A plurality of guide holes 365 guides the droplets of the liquid material from diffusion space 362 to outlet space 366. Also, guide space 364 is not limited to the one described above. For example, middle case 374 may be formed with a simple cylinder. In this case, guide space 364, which is a space within middle case 374, may be formed with a cylinder having the diameter the same as the diameter of the lower end of diffusion space 362 (the diameter of outlet space 366).

The droplets of the liquid material supplied along with the carrier gas through inlet 361 from liquid material supply 300A are vaporized to become the raw gas while passing sequentially through diffusion space 362, guide holes 365, outlet space 366 within vaporization chamber 360 of case 370 heated by heaters 392, 394.

The raw gas is adapted to be discharged outside from outlet space 366 through raw gas delivery outlet 380 provided at the sidewall of bottom case 376. Specifically, raw gas delivery outlet 380 includes a raw gas delivery pipe 382 connected to delivery outlet 378 formed at the sidewall of lower case 376, and a mist trap portion 390 configured to close raw gas delivery pipe 382. Raw material delivery gas pipe 382 is attached vertically to the sidewall of lower case 376, and is extended horizontally. At an end 384 of the downstream side of raw gas delivery pipe 382, a flanged joint 386 is attached which is connected to raw gas supply pipe 132. Mist trap portion 390 herein is fixed removably by flanged joint 386 in order to close the opening of end 384 of raw gas delivery pipe 382.

Mist trap portion 390 traps the droplet-shaped liquid material without allowing it to be passed, and includes an air-permeable member having an air permeability for allowing the raw gas obtained from the vaporization of the liquid material to be passed. As to such air-permeable member, it is preferable to adopt a mesh finer than the diameter of the droplets of the liquid material. Also, as to the constitution material of the air-permeable member, it is preferable for the material to have a high thermal conductivity and an easy-to-rise temperature characteristic. The material that satisfies these conditions includes metal, such as stainless steel having a porous structure or a mesh structure. Besides these materials, ceramics or plastics having a high thermal conductivity may be used. Here, since the entire raw gas delivery outlet 380 is covered by heater 394, mist trap portion 390 is also heated by heater 394.

As described above, by providing mist trap portion 390 at delivery outlet 378 of the raw gas, for example, the droplets of the liquid material left without being totally vaporized at vaporization chamber 360 can be trapped by mist trap portion 390 heated by heater 394 and are vaporized, thereby passing through mist trap portion 390 as well.

Also, a first temperature sensor (for example, a thermocouple) 152 is provided at case 370 to monitor the heating temperature by heaters 392, 394, particularly the temperature of vaporization chamber 360, at controller 150, so that the temperature of vaporization chamber 360 can be maintained at a predetermined setting temperature. Also, a second temperature sensor (for example, a thermocouple) 154 is provided near discharge outlet 322 of nozzle 320 of heated member 340 to monitor the heating temperature by heater 342, particularly the temperature of discharge outlet 322, at controller 150, so that the temperature of the vicinity of discharge outlet 322 can be maintained at a predetermined setting temperature.

In this case, it is preferred that the temperature of discharge outlet 322 is set in such a way that at least the accretion is not attached to discharge outlet 322, for example, at 100° C. to 140° C. and above. It is also preferred that the temperature of vaporization chamber 360 is set to be higher than that of discharge outlet 322, for example, 120° C. to 160° C. and above. Here, the temperature of discharge outlet 322 is set to be, for example, 120° C., and the temperature of vaporization chamber 360 is set to be, for example, 140° C.

According to this, it is possible to improve the vaporization efficiency in vaporization chamber 360, while maintaining the temperature of discharge outlet 322 so that at least the accretion is not attached to discharge outlet 322. Also, the temperature in vaporization chamber 360 is controlled to be higher than the temperature of discharge outlet 322, thereby the entire vaporizer 300 may be configured in such a way that a temperature gradient is increased from the upstream side to the downstream side. In other words, the part in which the liquid material flows has the lowest temperature, discharge outlet 322 is heated to a temperature so that the accretion is not attached, and vaporization chamber 360 is heated to a higher temperature than that of discharge outlet 322. With these features, the liquid material is not thermally decomposed in the way to discharge outlet 322 after passing through fine hole 316, thereby preventing the accretion from being attached to discharge outlet 322 and improving the vaporization efficiency in vaporization chamber 360.

Also, second temperature sensor 154 is provided as close as possible to discharge outlet 322, thereby controlling the heating temperature of discharge outlet 322 to be a desired temperature more accurately. Also with this, the unnecessary heating at fine hole 316 where the liquid material flows can be avoided.

### Operation of Deposition System

The operation of deposition system 100 according to the present embodiment will be described with reference to drawings. When generating the raw gas by vaporizer 300, vaporization chamber 360 and mist trap portion 390 are heated by heaters 392, 394 in advance, and heated member 340 is heated by heater 342 in advance.

First, controller 150 adjusts the opening degree of liquid material flow control valve 114, and supplies a predetermined amount of liquid material from liquid material supply 110 to vaporizer 300 via liquid material supply pipe 112. At the same time, controller 150 adjusts the opening degree of carrier gas flow control valve 124, and supplies a predetermined amount of carrier gas from carrier gas supply 120 to vaporizer 300 via carrier gas supply pipe 122.

By doing these, the liquid material from liquid material supply pipe 112 is stored temporarily at liquid storage chamber 310. At this time, valve body 334 is driven by actuator 330 to open liquid entrance 312 of fine hole 316, so that the liquid material passes through fine hole 316, and turned into droplets to be discharged from discharge outlet 322 of nozzle 320. Also, the carrier gas from carrier gas supply pipe 122 is ejected from carrier gas ejection port 326 via carrier gas supply passage 324. In this way, the droplets of the liquid material discharged from discharge outlet 322 are mixed with the carrier gas discharged from carrier gas ejection port 326 at mixing chamber 344. The droplets are then accelerated after being passed through throttle hole 352, and are turned into finer droplets to be discharged toward vaporization chamber 360. At this time, since heated member 340 is heated to the predetermined temperature, the accretion is not attached to discharge outlet 322 even if discharge outlet 322 is exposed to the carrier gas.

At vaporization chamber 360, the droplets of the liquid material introduced with the carrier gas from inlet 361 are diffused by diffusion space 362, and are introduced to outlet space 366 via each of guide holes 365 of guide space 364. At this time, since each of spaces of vaporization chamber 360 is heated to a predetermined temperature separately from heated member 340, most of the droplets of the liquid material are vaporized at each of the spaces of vaporization chamber 360 to become the raw gas and is introduced to delivery outlet 378. The raw gas is then delivered to raw gas supply pipe 132 after passing mist trap portion 390 via raw material delivery pipe 382. Also, since mist trap portion 390 is heated to a predetermined temperature as well, the droplets which were not able to be vaporized at vaporization chamber 360 are also contacted to mist trap portion 390 to be vaporized instantly. The droplets are then turned into the raw gas to be delivered to raw gas supply pipe 132 after passing mist trap portion 390.

The raw gas delivered to raw gas supply pipe 132 is supplied to film forming chamber 200, introduced to diffusion chamber 242 of shower head 240, and discharged from gas discharge hole 244 toward wafer W on susceptor 222. And the predetermined film, for example, HfO2 film is then formed on wafer W. Also, the flow of the raw gas introduced to film forming chamber 200 may be adjusted by controlling the opening degree of raw gas flow control valve 134 provided at raw gas supply pipe 132.

As described above, according to the present embodiment, discharge outlet 322 of the liquid material can be partially heated even separately from vaporization chamber 360, the liquid material that passes through fine hole 316 is not thermally decomposed during the flow. As a result, discharge outlet 322 is prevented from being clogged by the accretion and the vaporization efficiency is improved at vaporization chamber 360.

From the foregoing, although preferred embodiments of the present invention are described by referring to accompanying drawings, the present invention is not limited thereto. It will be appreciated that those skilled in the art can derivate various modifications and revisions within the scope and spirit claimed in following clams, and also these modifications and revisions fall within the scope of the present invention.

For example, the vaporizer according to the present invention is also applicable to a vaporizer used for MOCVD apparatus, plasma CVD apparatus, ALD (atomic layer deposition) apparatus, LP-CVD (batch type, vertical type, horizontal type, mini batch type) and the like.

### INDUSTRIAL APPLICABILITY

The present invention is applicable to a vaporizer for generating a raw gas after vaporizing a liquid material and a deposition system using the vaporizer.

### Explanation of Symbols

100: deposition system
110: liquid material supply
112: liquid material supply pipe
114: liquid material flow control valve
120: carrier gas supply
122: carrier gas supply pipe
124: carrier gas flow control valve
132: raw gas supply pipe
134: raw gas flow control valve
150: controller
152: first temperature sensor
154: second temperature sensor
200: film forming chamber
210: ceiling wall
212: bottom wall
222: susceptor
224: cylindrical support member
226: heater
228: power supply
230: exhaust port
232: exhaust system
240: shower head
242: diffusion chamber
244: gas discharge hole
300: vaporizer
300A: liquid material supply
300B: raw gas generator
301: penetrating hole
310: liquid storage chamber
311: liquid material introduction
312: liquid entrance
316: fine hole
318, 319: O-ring
320: nozzle
321: attachment member
322: discharge outlet
323: front end
324: carrier gas supply passage
326: carrier gas ejection port
330: actuator
332: attachment member
333: driving rod
334: valve body
340: heated member
342: heater
343: heater power source
344: mixing chamber
346: center space
348: ring-shaped space
350: throttle portion
352: throttle hole
354: upper taper portion
356: lower taper portion
360: vaporization chamber
361: inlet
362: diffusion space
364: guide space
365: guide hole
366: outlet space
370: case
372: upper case
374: middle case
376: lower case
378: delivery outlet
380: raw gas delivery outlet
382: raw gas delivery pipe
384: end
386: flanged joint
390: mist trap portion
392, 394: heater
395: heater power source
W: wafer

1. A vaporizer characterized by comprising:
a liquid storage chamber that is supplied with a liquid material having a predetermined pressure;
a nozzle disposed to be projected from the liquid storage chamber and configured to discharge the liquid material retained at the liquid storage chamber;
a vaporization chamber that vaporizes the liquid material discharged from a discharge outlet of the nozzle to produce a raw gas and deliver the raw gas from a delivery outlet;
a cylindrical heated member configured to cover the vicinity of the discharge outlet between the front end of the nozzle and the vaporization chamber;
a carrier gas ejection port provided at the heated member and configured to eject the carrier gas from the vicinity of the discharge outlet;
a mixing chamber partitioned within the heated member and configured to mix the liquid material discharged from the discharge outlet with the carrier gas to eject a mixture of the liquid material and the carrier gas to the vaporization chamber;
a first heating part configured to heat the vaporization chamber from an exterior; and
a second heating part configured to heat the heated member from an exterior.

2. The vaporizer as claimed in claim 1, wherein the heated member is made of metal, and the nozzle is made of resin.

3. The vaporizer as claimed in claim 2, wherein the mixing chamber is partitioned by a throttle portion provided at the heated member, the throttle portion is formed with a throttle hole communicating between the mixing chamber and the vaporization chamber, and the throttle portion is configured to be heated along with the heated member by the second heating part.

4. The vaporizer as claimed in claim 3, wherein the mixing chamber is formed with a central space at a lower side of the discharge outlet and a ring-shaped space surrounding the central space, and the carrier gas ejection port is arranged to eject the carrier gas to the ring-shaped space.

5. The vaporizer as claimed in claim 4, wherein at the mixing chamber side of the throttle portion, an upper tapered portion is provided allowing diameter of the throttle hole to be enlarged gradually toward the mixing chamber, and the upper tapered portion is formed to be projected toward the discharge outlet.

6. The vaporizer as claimed in claim 5, wherein at the vaporization chamber side of the throttle portion, a lower tapered portion is provided allowing diameter of the throttle hole to be enlarged gradually toward the vaporization chamber, and the lower tapered portion is formed to be projected toward the vaporization chamber.

7. The vaporizer as claimed in claim 1, further comprising a first temperature sensor configured to detect temperature of the vaporization chamber, a second temperature sensor configured to detect temperature of the discharge outlet, and a controller configured to monitor temperatures of each of the temperature sensors, control temperature of the discharge outlet so that at least the accretions are not attached to the discharge outlet, and control temperature of the vaporization chamber to be higher than that of the discharge outlet.

8. A film forming system characterized by having a film forming chamber that performs a film forming process over a substrate to be processed by introducing a raw gas from a vaporizer that vaporizes a liquid material to produce the raw gas, the vaporizer comprising:
a liquid storage chamber that is supplied with a liquid material having a predetermined pressure;
a nozzle disposed to be projected from the liquid storage chamber and configured to discharge the liquid material retained at the liquid storage chamber;
a discharge outlet opened at a front end of the nozzle;
a vaporization chamber that vaporizes the liquid material discharged from the discharge outlet to produce the raw gas;
a delivery outlet configured to deliver the raw gas from the vaporization chamber to the film forming chamber;
a cylindrical heated member configured to cover the vicinity of the discharge outlet between the front end of the nozzle and the vaporization chamber;
a carrier gas ejection port provided at the heated member and configured to eject the carrier gas from the vicinity of the discharge outlet;
a mixing chamber partitioned within the heated member and configured to mix the liquid material discharged from the discharge outlet with the carrier gas to eject a mixture of the liquid material and the carrier gas to the vaporization chamber;
a first heating part configured to heat the vaporization chamber from an exterior; and
a second heating part configured to heat the heated member from an exterior.
